(19) United States
(12) Patent Application Publication
(10) Pub. No.: US 2024/0154077 A1
(43) Pub. Date: May 9, 2024

(54) High-Power Silicon LED Package Of Solid Cavity Design

(71) Applicant: Gerald Ho Kim, Spokane, WA (US)

(72) Inventor: Gerald Ho Kim, Spokane, WA (US)

(21) Appl. No.: 18/387,876

(22) Filed: Nov. 8, 2023

Related U.S. Application Data
(60) Provisional application No. 63/423,774, filed on Nov. 8, 2022.

(51) Int. Cl. H01L 33/60; H01L 25/075; H01L 33/62

(52) U.S. Cl. CPC H01L 33/60; H01L 25/0753; H01L 33/62

(57) ABSTRACT

A flip-chip package includes a light source, a silicon base plate, a silicon reflector, and a cover. The light source includes a piece of Light-Emitting Diode (LED) in flip-chip configuration. The silicon base plate includes a piece of silicon with electrical pads to bond the light source, two etched, square, via-holes to provide electrical connection to the bottom of the silicon base plate, and filling port for liquid epoxy. The silicon reflector includes a chemically etched silicon piece to form an angled reflector where the light radiation from the light source reflects on the surface of the angled reflector and a recess forms on the top surface of the silicon reflector. The cover includes a piece of window material that transmits the light radiation of the light source.

### CROSS-REFERENCE TO RELATED PATENT APPLICATION(S)

The present disclosure claims the priority benefit of U.S. Patent Application No. 63/423,774, filed 8 Nov. 2022, the content of which herein being incorporated by reference in its entirety.

### BACKGROUND OF INVENTION

This invention extracts more light power from flip-chip LED die using a silicon MEMS package design. Many UV LED dies are grown on a sapphire substrate, and a laser scribing machine cuts these LED dies and cleaves them to fabricate them into a final UV LED die. Then the die is attached to a ceramic, metal, or silicon substrate, where the die is electrically connected and sealed with a cover window.

A UV LED package consists of a cover, a light source, a silicon reflector, and a silicon base plate. The light source mounts on the electrical pads of the silicon base plate, and the silicon reflector has a recess, angled reflectors, and channels. The recess is made to bond a lens to seal the UV LED package, and a flat window can also be mounted to close the package. The recess captures the cover like a half-ball lens to precisely fit into it and the recess is made with a chemical etching process so that I show a sloped angle of the recess pocket. The recess can be made with a dry-etching process; however, it adds a higher cost to the silicon reflector. The recess depth is determined by the separation gap between the cover and the top of the light source. If the separation gap is too wide, then the light generated in the emission zone propagates more distance, and the beam divergence of the light source is wide. The separation gap is minimized as much as possible. The recess depth is calculated by maintaining the separation gap in the range of 0.05 mm to 0.3 mm.

The silicon reflector is bonded to the silicon base plate to form a cavity filled with an index-matching material for better UV light extraction. And also, the silicon base plate has two chemically etched holes that provide electrical feed-through to light up the light source and a filling port for the index-matching material. The UV LED package design focuses on a flip-chip configuration of the UV LED chip.

The holes in the silicon base plate are etched by an anisotropic method; therefore, the shape of the hole is a pyramid pattern. The holes etch from both sides of the silicon base plate, and the pyramid patterns are etched until the holes connect. This etching method of creating via-hole is used in this design due to reducing the cost and lower manufacturing time of using a laser drilling process. Then, these holes get metalized and filled with electrically conducting material to connect the silicon base plate's top and bottom sides. Because of the simultaneous etching from both sides, the holes' size is similar.

There are two different types of UV LED die depending on the electrical connection configuration: flip-chip or lateral LED configuration. Typically, the UV emitting structure is grown on a base substrate such as a sapphire or silicon-carbide wafer. The flip-chip LED configuration bonds the UV-emitting structure to the base substrate, and the lateral LED configuration detaches the UV-emitting structure from the base substrate. Most infrared radiation (IR) LED, UVA LED, and visual spectrum LED use the lateral design of the LED package. However, the production process of the lateral design uses an expensive detaching process of laser lift-off and can cause a low yield issue in UV LED. However, UVC and UVB LED predominately use the flip-chip configuration for better production yield and a simpler process.

Sometimes the lateral LED configuration produces a better performance than the flip-chip LED configuration, and the flip-chip LED configuration has an issue with scattering and Fresnel loss at the interface of the base substrate where the radiation of LED light emits. The base substrate, such as sapphire or silicon carbide, is a hard material, and a laser scribing machine cuts these materials, and then it is cleaved. The laser scribing surfaces are very rough surfaces due to a melting process of the base substrate of sapphire or silicon carbide. As a result, the light generated in the flip-chip configuration gets a high scattering loss at all laser-cut surfaces.

For the flip-chip configuration, the light is emitted from the bottom of the UV LED die that mounts on a base plate such as ceramic, metal, or silicon substrate for electrical connection and heat sink purposes. Then, the LED light emits through the sapphire substrate and reaches out to a cover window in the LED package. Sometimes, the LED light generated at the emission zone (multi-quantum walls) travels through the sapphire substrate or comes out to the side or top of the sapphire substrate. Then, the LED light propagates continuously to the cover window or the side walls emitting from the UV LED die. Finally, an angled reflector is placed around the UV LED die to bring the light out from the top side of the UV LED die and redirects the UV light to the top side of the base substrate.

One method of fabricating an angled reflector is using an anisotropic ally etched silicon piece coated with a shiny metal such as aluminum or silver film; however, the aluminum coating works well with a wideband of the UV spectrum. A vertically deep, etched silicon piece can reflect the light emitted from the side walls of the laser-cut sapphire substrate. However, it is difficult to etch a mirror finish surface to reflect light effectively using a deep RIE (reactive ion etching) process. In addition, the vertical wall doesn't direct the UV light to the top of the cover window. At the bottom of the silicon, the reflector has a channel connecting the angled reflector to the hole once the silicon reflector bonds to the silicon base plate. The channel's purpose is to fill the cavity through the hole in the silicon base plate. And also, the channel allows purge any air in the cavity while an index-matching material is being filled.

This patent emphasizes filling the cavity with index-matching material with high transmission at the wavelength of the light source. In addition, the index-matching material can minimize Fresnel loss and rough surface loss. The index-matching material can be optical epoxy or clear liquid. The material can fill in the cavity 100%, but it causes an issue of thermal expansion. The index-matching material needs to fill around the light source and the separation gap. The material is filled at a minimum of 50% to 90% to get the maximum light extraction and prevent high pressure caused by thermal expansion.

It is important to understand the structure of a light source for the flip-chip configuration of a UV LED. First, an emission zone is grown on the top of a substrate, sapphire, and mounted as a flip-chip configuration. The emission zone has two electrical pads that provide an electrical connection. The UV radiation from the emission zone emits to the substrate, sapphire, toward the side and top of the substrate. If the UV LED chip has a clear cut to form a UV LED die, the UV radiation doesn't have a lot of loss at the interface when the radiation emits from the substrate. In addition, a perfectly smooth surface of the side wall of the substrate has a Fresnel loss of a few percent depending on the index of refraction difference. Typically, the UV LED die processes with laser cut and mechanical cleave methods. Initially, the substrate cuts with a laser abrasion process, where it melts to create a rough surface. The experiment shows the rough surface has not only the Fresnel loss but also a significant scattering loss. Due to both losses to extract maximum radiation, an index-matching material is filled around the substrate in a UV LED packaging to minimize the Fresnel loss and scattering loss. The design of the UV LED package reduces these losses and increases the radiation extraction efficiency by more than 2 to 3 times. In addition, the package design improves a typical beam divergence of 120 degrees to a tighter beam divergence of 80 degrees combined with a silicon-angled reflector.

The substrate, sapphire, of the light source need a sufficiently large height of the side wall to bring out the radiation emitted from the emission zone. If the height of side wall is small, then the most of the radiation from the light source comes out from the top of the substrate. The most reasonable thickness of sapphire wafer is used in the range of 0.1 to 0.7 mm. If the height is out of this range, the cavity filling of this package design isn't highly effective.

This invention looks at developing a better LED package to minimize any loss on each interface of all surfaces where the LED light is reflected or scattered at these surfaces as the LED light emits from the emission zone. The first approach is to minimize the scatter loss at the side wall of the sapphire substrate, where laser scribing and cleaving are performed. However, the laser scribing process creates rough melting and cutting patterns on the side of the sapphire substrate, and a good portion of LED light is scattered and lost at the laser-cut surface. As a result, the LED light can't propagate through the sapphire substrate's side wall due to scattering and Fresnel loss at the side wall.

To minimize the scatter and Fresnel loss at the side wall of the base substrate, an index-matching material is placed around all sides of the laser-cut sapphire area. Then, the LED light from the emission zone is transmitted through the side walls of the base substrate, sapphire, going through the index-matching material. Finally, a silicon reflector coated with the aluminum film is placed around the UVC LED dies for a maximum emission of the UVC LED radiation. In this case, the UVC light from the side wall is measured by subtracting the side-wall emission from the total UV LED light with/without the index matching material and the aluminum reflector. One measurement shows a 3 to 5% improvement in the LED light collection using a silicon reflector with angled reflectors. It is an insignificant improvement of the LED light contribution from the side wall emission without the index-matching material. The index-matching material should be similar to the sapphire material (an index of refraction, n=˜1.7), and any organic or inorganic material such as carbon-fluorine compound (n=˜1.4) or sodium silicate (n=˜1.4.) The difference in the index of refraction can be in the range of n=0 to 0.5. For example, pure water of n=˜1.3 can fill in the surrounding of the UVC LED dies with the silicon reflector, and the index of the refraction difference is about 0.4.

The total emission power of the UV LED package for the flip-chip configuration increases as the index-matching material is filled in a cavity created by assembling a light source, a silicon base plate, a silicon reflector, and a cover. First, the cavity fills with an index-matching material minimizing scattering and Fresnel loss at the interface of the side wall of the substrate. These losses get improved by filling an index-matching material that can transmit the UV LED light without significant absorption loss. Then, the LED light is reflected by a silicon reflector coated with aluminum film.

This invention is designed to extract most of the UV light from a flip-chip or lateral packaged UV LED using an index-matching material and a silicon reflector fabricated by an anisotropic etching technique of single-crystal silicon. An important design parameter is how closely the silicon reflector is placed from a base substrate, sapphire, used in fabricating the flip-chip LED die. As a result, the silicon reflector is closely placed to the side of the base substrate, sapphire, from the UV flip-chip LED. As a result, the UVC light emitted from the top surface of the UV LED die has increased as little as 3 to 5% without filling the cavity between the side wall of the sapphire substrate and the side reflector of the silicon piece. Then, an index-matching material fills the cavity, and the UV light power increases significantly to 30 to 40%. This design approach shows how important to minimize the scattering loss and Fresnel loss at the interface of the side wall of the sapphire substrate that is laser-cut and cleaved.

The scatting loss is minimized by removing a rough surface of the laser-cut area by filling it up with an optically index-matching material. This design also lowers a Fresnel loss at the interface by reducing the index of refraction difference. As a result, the original UV light generated at the bottom of the flip chip is emitted from the side of the sapphire substrate without significant scattering loss at the laser-cut area. Therefore, the UV light is refracted at the sapphire substrate propagating toward the top side of the flip-chip die without much loss. It is a crucial design to minimize the scattering and Fresnel loss since the UV light reflected on the interface surface is absorbed in the UV chip and causes more thermal heating.

The design of a silicon reflector and an index-matching material has a limitation on placing the distance between the side wall of the sapphire substrate in UV LED die and the silicon reflector. For example, the height of the side wall of the sapphire substrate is 0.4 mm, and the height of the silicon reflector is 0.5 mm. The silicon reflector etches at a 54.74-degree angle in single-crystal silicon of <100> face orientation etching along the silicon crystal plane of <111>.

The UV light is reflected off this angled surface and on the top side of a cover window used in the flip-chip UV LED package. The bottom edge of the silicon reflector is placed almost 0.05 mm away from the sapphire substrate's side wall, and an index-matching material, UV optical epoxy, is filled between the side wall and the silicon reflector. As a result, the UV light emitted from the top side of the UV LED package using a flat window improves by about 15%, and mounting a half-ball lens on the top of the silicon reflector emits more than 30 to 40%. In some cases, the UV light emission improves by as much as 70 to 80% range.

The edge of the silicon reflector places almost 1.5 times 0.6 mm, the distance away from the height of the sapphire substrate 0.4 mm, and the cavity is filled with UV epoxy and a cover window. As a result, the UV light power dropped to 10 to 15%. This design approach clearly shows a relationship between the placement distance of the silicon reflector's edge and the sapphire substrate's side wall filled with an index-matching material such as silicone or other optical epoxies. This design is optimized by the performance of UV light extraction efficiency limited by the distance placement that needs to be less than 1.5 times shorter than the height of the UV LED dies. For example, suppose the placement distance of the UV LED die and the silicon reflector is more significant than 1.5 times the height of the UV LED dies. In that case, the UV light extraction is poor, and the cost of building an efficient UV LED package increases significantly due to a large amount of index-matching material and the physical size of the UV LED package.

### FIGURE EXPLANATION

FIG. 1 shows a flip-chip package (100) that consists of a light source (120), a silicon base plate (140), a silicon reflector (130), and a cover (110).

FIG. 2A shows a projected view of a light source (120), an emission zone (122), and a substrate (123).

FIG. 28 shows a projected bottom view of a light source (120), an emission zone (122), a substrate (123), and electrical pads (124 & 125). The electrical pad (124) can be a negative, or the electrical pad (125) can be a positive electrical pad, or vice versa.

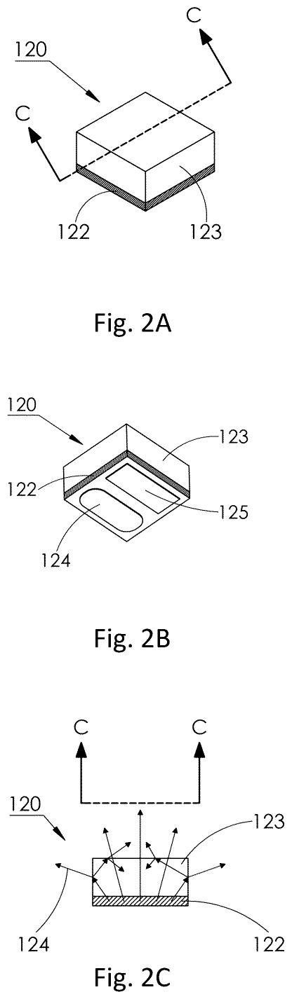

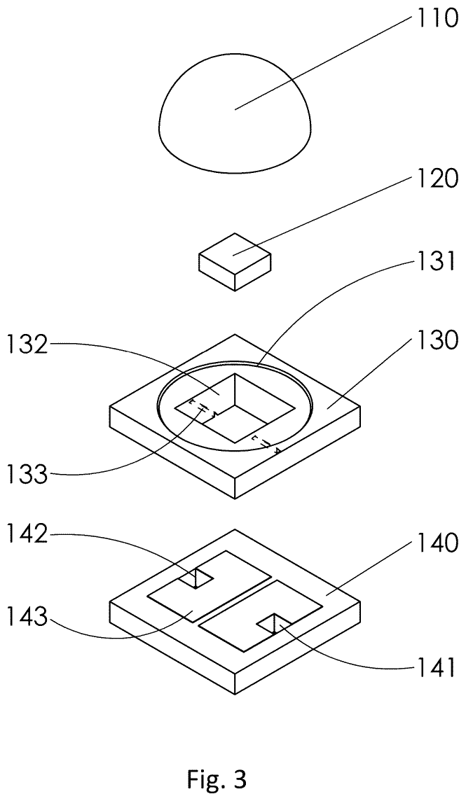

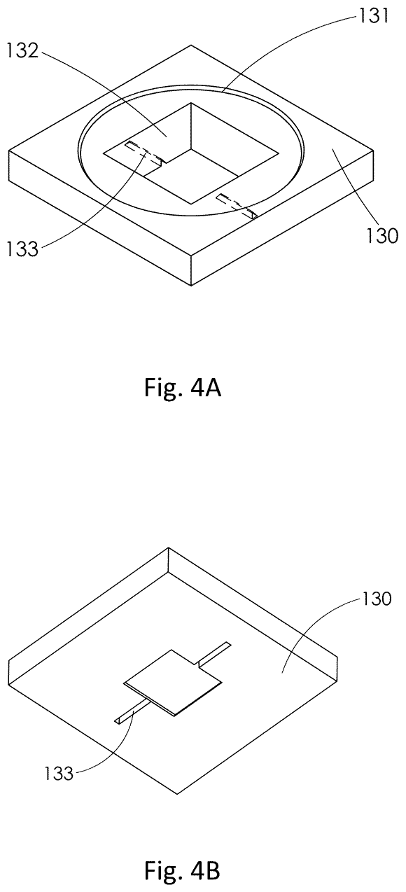

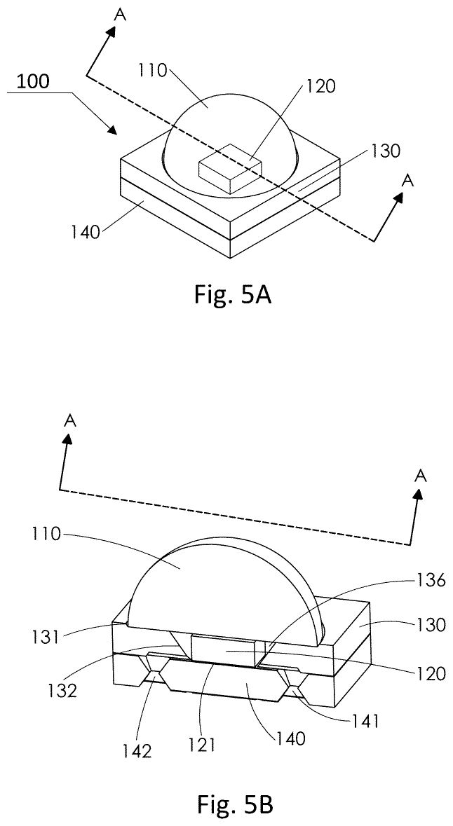

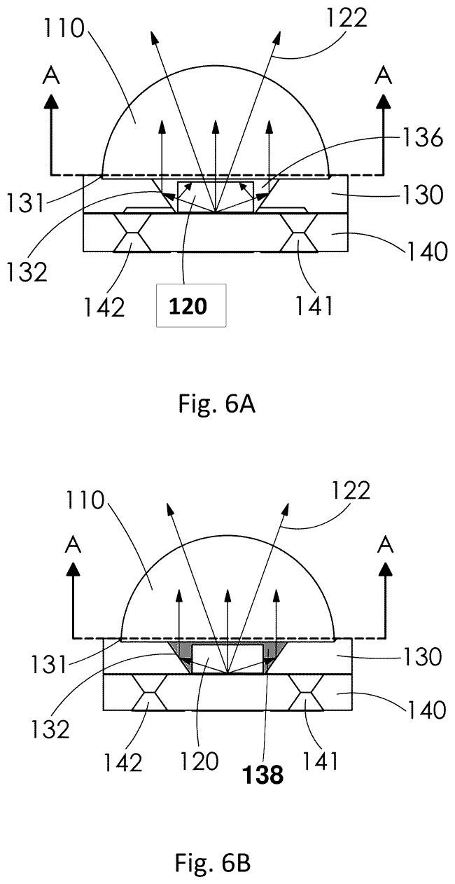

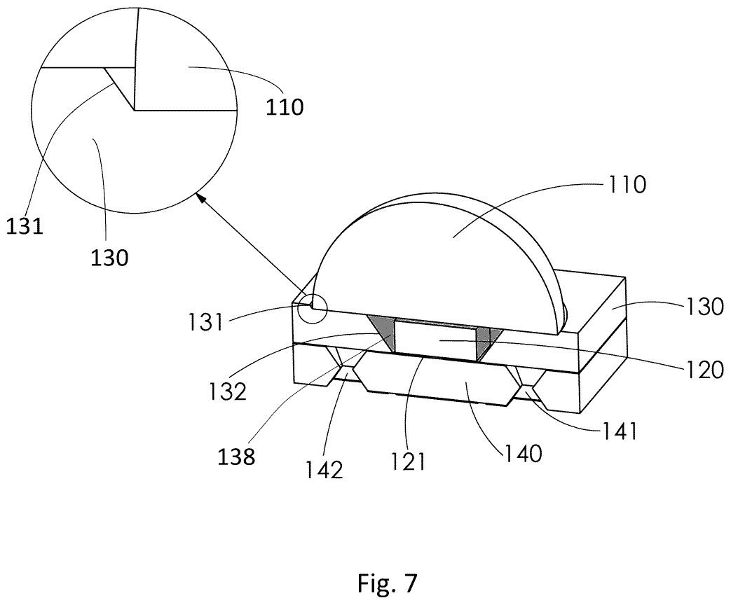

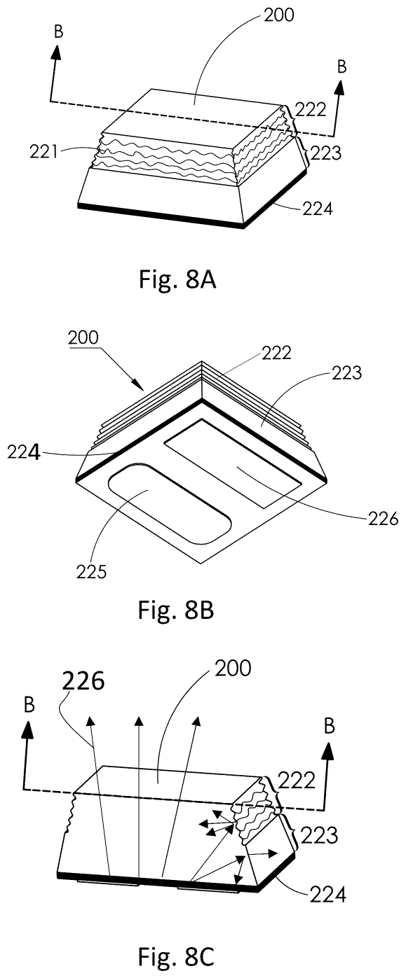

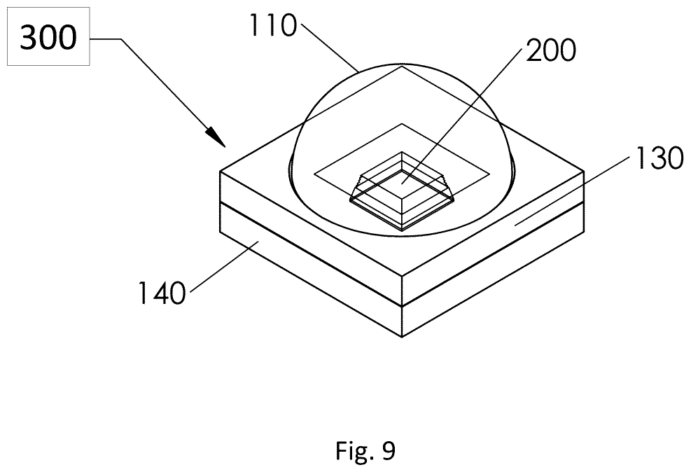

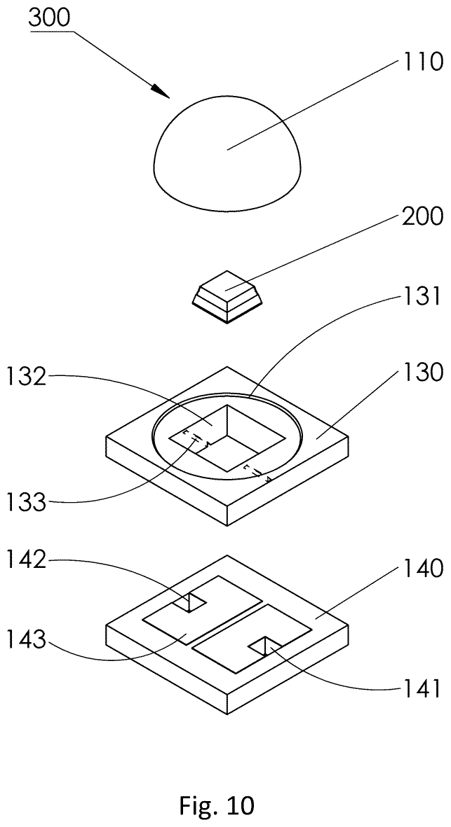

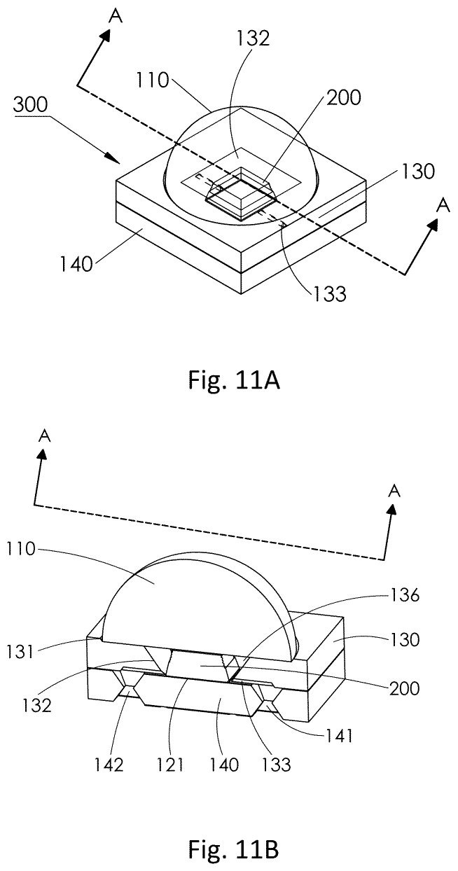

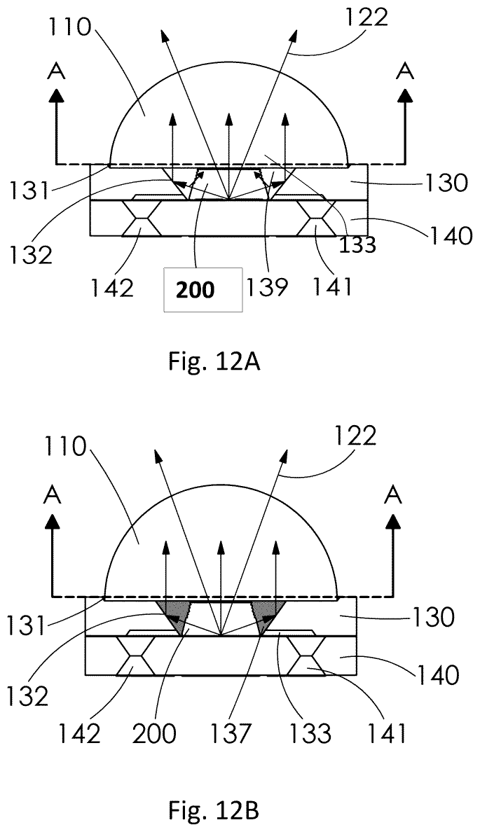

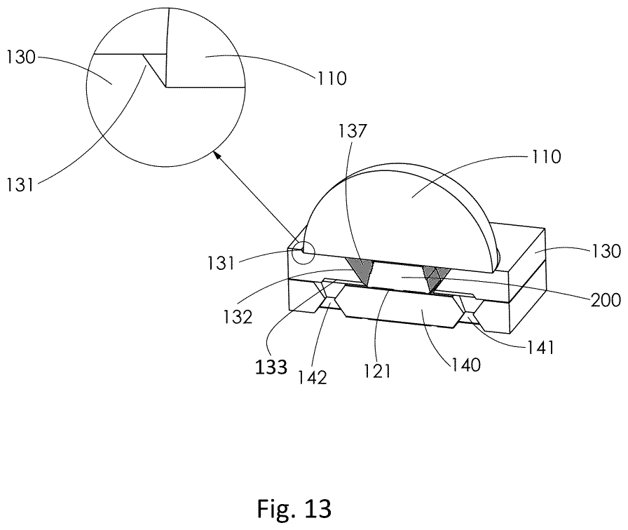

FIG. 2C shows a cross-sectional view of the cutline of CC along with the propagation of the light radiations (124). An illustration view of the light radiation (124) shows the light radiation is reflected and refracted on the surfaces of the substrate (123).

FIG. 3 shows an exploded view of all components of the flip-chip package (100), where a cover (110) is illustrated as a half-ball lens mounted on a silicon reflector (130). The silicon reflector (130) has a distinctive feature of an etched, square shape, angled reflector (132). The angled or slope surface is a naturally etched surface of single crystal silicon of faced plane <100> in KOH anisotropic etching of silicon. Also, a circle pattern of a recess (131) etches on the top of the silicon reflector (130). A circular shape of a half-ball lens or flat window can be mounted on the recess (131). A light source (120) is also attached to a silicon base plate (140) where the electrical connections (124 & 125) in FIG. 2B of the light source (120) are patterned. The electrical contacts (124 & 125) are electrically bonded to metal pads (143). Two etched square holes (141 & 142) are metalized for electrical connection to the bottom of the silicon base plate (140), and these holes are also used for filling a cavity (136) in FIG. 4B formed by assembling all components of the flip-chip package (100.)

FIG. 4A shows a projection view of a silicon reflector (130) and a recess (131) for a cover (110). A rectangular shape of an angled reflector (132) is etched, and a channel (133) is etched on the backside of the silicon reflector (130).

FIG. 4B shows the backside of the silicon reflector (130), and the channel (133) is shown in the backside of the projected view.

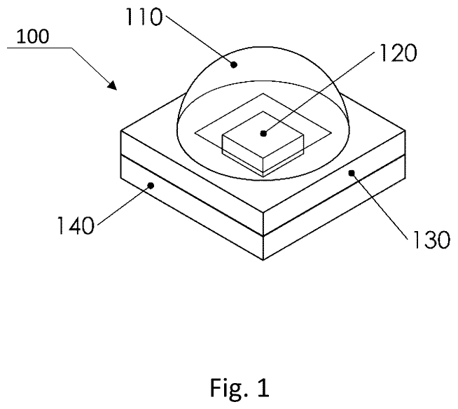

FIG. 5A shows a flip-chip package (100) that is assembled with a light source (120), a silicon base plate (140), a silicon reflector (130), and a cover (110). and showing all the same components listed in FIG. 1 along with a cross-cut line of AA.

FIG. 5B shows a projected cross-sectional view of the flip-chip package (100) where the cover (110) is fit to a recess (131) in a silicon reflector (130). The angled reflector (132) is shown in the silicon reflector (130), and a cavity (136) is formed by the angled reflector (132) and the side of the light source (120) shown in this Figure. The cavity (136) is formed by assembling the light source (120), the silicon base plate (140), the silicon reflector (130), and the cover (110). A light source (120) is bonded to a silicon base plate (140), and two etched square holes (141 & 142) are shown as squared-through holes in the cross-sectional view. The etched holes (141 & 142) are an equal distance of square holes etched from both sides of the silicon base plate (140).

FIG. 6A shows a front-face view of the cross-sectional view shown in FIG. 4A. All displayed components are the same as shown in FIG. 4A, and radiation (122) is sketched on the drawing. The UV radiation (122) impinges on the side of the light source (120), creating a reflected UV light and transmitted UV light at the surface of the light source (120). The cavity (136) is formed by assembling the light source (120), the silicon base plate (140), the silicon reflector (130), and the cover (110). The cover (110) is fit to a recess (131) in the silicon reflector (130).

FIG. 6B shows a front-face view of the cross-sectional view shown in FIG. 4A, similar to FIG. 5A; however, the cavity (136) in FIG. 5A has filled with a cavity filler (138). The cavity filler (138) reduces any reflected radiation (122) at the surface of the light source (120) due to the index-matching material.

FIG. 7 shows an expanded view of a recess (131) etched on a silicon reflector (130) that is fitted with a cover (110), and the cavity filler (138) is presented in the cross-sectional view.

FIG. 8A shows a projected view of a light source (200), a LED emission zone (224), and a substrate (221) is shown. The substrate (221) has two separated zones a rough surface zone (222) and a smooth surface zone (223).

FIG. 8B shows a projected bottom view of a light source (200), an emission zone (224), a substrate (221), and electrical pads (225 & 226). The electrical pad (225) can be a negative pad, and the electrical pad (226) can be a positive pad or visa verse. A rough surface zone (222) and smooth surface zone (223) are also shown in the substrate (221).

FIG. 8C shows a cross-sectional view of the cutline of BB along with the propagation of the light radiations (226). An illustration view of the light radiation (226) impinging on the rough surface zone (222) gets high scattering loss, and the smooth surface zone (223) receives a better transmission of the light radiation (226) and some internal reflection of the light radiation (226).

FIG. 9 shows a flip-chip package (300) that consists of a light source (200), a silicon base plate (140), a silicon reflector (130), and a cover (110).

FIG. 10 shows an exploded view of all components of the flip-chip package (300), where a cover (110) is illustrated as a half-ball lens mounted on a silicon reflector (130). The silicon reflector (130) has a distinctive feature of an etched, square shape, angled reflector (132). The angled or slope surface is a naturally etched surface of single crystal silicon of faced plane <100> in an anisotropic etching process. Also, a circle pattern of a recess (131) etches on the top of the silicon reflector (130). A circular shape of a half-ball lens or flat window can be mounted on the recess (131). A light source (200) is also attached to a silicon base plate (140), where the electrical connections (225 & 226) in FIG. 8B of the light source (200) are patterned. The electrical pads (225 & 226 in FIG. 8B) are bonded to metal pads (143). Two etched square holes (141 & 142) are metalized for electrical connection to the bottom of the silicon base plate (140), and these holes are also used for filling a cavity (139) in FIG. 12A formed by assembling all components of the flip-chip package (300.) The cavity (139) is also connected through the square holes (141 & 142) and the channels (133).

FIG. 11A shows a flip-chip package (300) and shows the cover (110), light source (200), silicon reflector (130), and silicon base plate (140) along with a cross-cut line of AA.

FIG. 11B shows a projected cross-sectional view of the flip-chip package (300) where a cover (110) is fit to a recess (131) in a silicon reflector (130). The angled reflector (132) is shown in the silicon reflector (130), and a cavity (139) forms by the angled reflector (132), the cover (110), and the side of the light source (200) shown in this Figure. The cavity (139) forms by assembling the light source (200), the silicon base plate (140), the silicon reflector (130), and the cover (110). A light source (200) bonded to a silicon base plate (140), and two etched square holes (141 & 142) are shown in Figure as squared through holes in the cross-sectional view. The etched holes (141 & 142) are an equal distance of square holes etched from both sides of the silicon base plate (140).

FIG. 12A shows a front-face view of the cross-sectional view shown in FIG. 11A. All displayed components in FIG. 10, such as a cover (110), light source (200), silicon reflector (130), and silicon base plate (140), are assembled along with radiations (122). The radiation (122) is impinging on the side of the light source (200), creating reflected light and transmitted light at the interface of the light source (200). The cavity (139) forms by assembling the light source (200), the silicon base plate (140), the silicon reflector (130), and the cover (110). The cover (110) is fit to a recess (131) in the silicon reflector (130).

FIG. 12B shows a front-face view of the cross-sectional view shown in FIG. 11A, similar to FIG. 12A; however, the cavity (139) in FIG. 12A has filled with a cavity filler (137). The cavity filler (137) reduces any reflected radiation (122) at the interface of the light source (200) due to minimizing the index of refraction difference between the substance (221) and the cavity filler (137).

FIG. 13 shows an expanded view of the recess (131) etched on a silicon reflector (130), fits with a cover (110), and the cavity filler (137), presented in the detailed view.

What is claimed is:

1) A flip-chip package comprising:
a light source, comprising:
a piece of Light-Emitting Diode (LED) in flip-chip configuration where a light radiation is transmitted through a substrate that has a sufficient height compared to the size of an emission zone, and the light radiation is emitted from four side walls and the top of the substrate where apposite to the emission zone,
a silicon base plate comprising:
a piece of silicon with electrical pads to bond the light source, two etched, square, via-holes to provide electrical connection to the bottom of the silicon base plate, and filling port for liquid epoxy,
a silicon reflector comprising:
a chemically etched silicon piece to form an angled reflector where the light radiation from the light source reflects on the surface of the angled reflector and a recess forms on the top surface of the silicon reflector, and also two channels forms at the bottom of the silicon reflector,
a cover, comprising:
a piece of window material that transmits the light radiation of the light source where the cover fits the recess of the silicon reflector to form a cavity around the light source combined with the silicon base plate, where a cavity filler is filled in the cavity formed by assembling the silicon base plate, the silicon side reflector and the cover.

2) The flip-chip package of claim 1, wherein the substrate of the light source is sapphire.

3) The flip-chip package of claim 1, wherein the sufficient height of the substrate is in the range of 0.1 mm to 0.7 mm.

4) The flip-chip package of claim 1, wherein the two etched holes of the silicon base plate are a pyramid shape of sufficiently equal size.

5) The flip-chip package of claim 1, wherein the channels connect a path of the etched holes and the cavity.

6) The flip-chip package of claim 1, wherein the cover is a flat window transmitting the light radiation of the light source.

7) The flip-chip package of claim 1, wherein the cover is a half ball lens fits into the recess tightly for transmitting the light radiation of the light source.

8) The flip-chip package of claim 1, wherein the silicon reflector is closely placed to the light source where a separation distance of the silicon reflector to the base substrate is sufficiently less than the height of the substrate.

9) The flip-chip package of claim 1, wherein the depth of the recess makes a sufficiently narrowed separation gap from the light source to the cover in the range of 0.05 mm to 0.3 mm.

10) The flip-chip package of claim 1, wherein the cavity is filled 50% to 90% with the cavity filler from the bottom surface of the cover.

11) A flip-chip package, comprising:
a light source, comprising:
a piece of Light-Emitting Diode (LED) in flip-chip configuration where a light radiation is transmitted through a substrate that has a sufficient height compared to the size of an emission zone, and the light radiation is emitted from four side walls, and the top of the substrate where apposite to the emission zone, and the side walls of the substrate has two distinctive surfaces,
a silicon base plate, comprising:
a piece of silicon with electrical pads to bond the light source, two etched, square, via-holes to provide electrical connection to the bottom of the silicon base plate, and filling port for liquid epoxy,
a silicon reflector, comprising:
a chemically etched silicon piece to form an angled reflector where the light radiation from the light source reflects on the surface of the angled reflector and a recess forms on the top surface of the silicon reflector, and also two channels forms at the bottom of the silicon reflector,
a cover, comprising:
a piece of window material that transmits the light radiation of the light source where the cover fits the recess of the silicon reflector to form a cavity around the light source combined with the silicon base plate where a cavity filler is filled in the cavity formed by assembling the silicon base plate, the silicon side reflector and the cover.

12) The flip-chip package of claim 11, wherein the substrate of the light source has a rough surface and smooth surface zone on the side wall of the substrate.

13) The flip-chip package of claim 11, wherein the sufficient height of the substrate is in the range of 0.1 mm to 0.7 mm.

14) The flip-chip package of claim 11, wherein the two etched holes of the silicon base plate are a pyramid shape of sufficiently equal size.

15) The flip-chip package of claim 11, wherein the channels connect a path of the etched holes and the cavity.

16) The flip-chip package of claim 11, wherein the cover is a flat window transmitting the light radiation of the light source.

17) The flip-chip package of claim 11, wherein the cover is a half ball lens that is fit into the recess transmitting the light radiation of the light source.

18) The flip-chip package of claim 11, wherein the silicon reflector is closely placed to the light source where a separation distance of the silicon reflector to the base substrate is sufficiently less than the height of the substrate.

19) The flip-chip package of claim 11, wherein the depth of recess is making a sufficiently narrowed separation gap from the light source to the cover in the range of 0.05 mm to 0.3 mm.

20) The flip-chip package of claim 11, wherein the cavity is filled 50% to 90% with the cavity filler from the bottom surface of the cover.
